(19) United States
(12) Patent Application Publication
(10) Pub. No.: US 2025/0239560 A1
(43) Pub. Date: Jul. 24, 2025

(54) SEMICONDUCTOR DEVICE

(71) Applicant: Mitsubishi Electric Corporation, Tokyo (JP)

(72) Inventors: Tetsuo YAMASHITA, Tokyo (JP); Yasutaka SHIMIZU, Tokyo (JP)

(73) Assignee: Mitsubishi Electric Corporation, Tokyo (JP)

(21) Appl. No.: 18/956,108

(22) Filed: Nov. 22, 2024

(30) Foreign Application Priority Data
Jan. 24, 2024 (JP) 2024-008717

(51) Int. Cl. H01L 23/00; H01L 25/065; H01L 29/16

(52) U.S. Cl. CPC H01L 24/49; H01L 24/08; H01L 24/48; H10D 62/8325; H01L 25/0655; H01L 2224/08054; H01L 2224/08113; H01L 2224/48179; H01L 2224/4917; H01L 2224/49175; H01L 2924/13055; H01L 2924/13063

(57) ABSTRACT

A semiconductor device includes: a plurality of semiconductor chips mounted to an insulating substrate; and a case housing them. The case has a gate terminal, a source sense terminal, a source terminal, and a drain terminal. The gate terminal and the source sense terminal are at different heights, and the source terminal is at a smaller height than the gate terminal and the source sense terminal.

### BACKGROUND OF THE INVENTION

### Field of the Invention

The present disclosure relates to semiconductor devices.

### Description of the Background Art

Technology of providing a height difference among a plurality of terminals (e.g., a bus bar, a lead, and a pad) of a semiconductor device has been proposed to facilitate wire bonding in the manufacture of the semiconductor device and miniaturize the semiconductor device (e.g., Japanese Patent Application Laid-Open No. 2012-89548 and Japanese Patent Application Laid-Open No. 6-181279). A “height” of a terminal herein refers to a height of an attachment position of the terminal and does not refer to a thickness of the terminal.

Japanese Patent Application Laid-Open No. 2012-89548 proposes a configuration in which two main terminals (a source terminal and a drain terminal) have a height difference but fails to take signal terminals (e.g., a gate terminal and a source sense terminal) into consideration to leave room for improvement in switching characteristics.

Japanese Patent Application Laid-Open No. 6-181279 takes heights of signal terminals into consideration and discloses main terminals arranged on an upper step and signal terminals arranged on a lower step. The arrangement, however, increases lengths of main wires connected to the main terminals to raise concerns about an increase in heat generated by the main wires. Reduction in lengths of the main wires is necessary to achieve a higher power density of a semiconductor device.

### SUMMARY

It is an object of the present disclosure to provide a semiconductor device enabling optimization of switching characteristics and a higher power density.

A semiconductor device according to the present disclosure includes: an insulating substrate; a drain pattern and a gate pattern formed over an upper surface of the insulating substrate; a plurality of semiconductor chips each having a drain electrode on a lower surface and a source electrode and a gate electrode on an upper surface, the drain electrode being bonded to the drain pattern; and a case housing the plurality of semiconductor chips and having a gate terminal, a source sense terminal, a source terminal, and a drain terminal. The drain terminal is connected to the drain pattern via a first wire. The source terminal is connected to the source electrode of each of the plurality of semiconductor chips via a second wire. The gate terminal is connected to the gate pattern via a third wire. The gate pattern is connected to the gate electrode of each of the plurality of semiconductor chips via a fourth wire. The source sense terminal is connected to the source electrode of any one of the plurality of semiconductor chips via a fifth wire. The gate terminal and the source sense terminal are at different heights. The source terminal is at a smaller height than the gate terminal and the source sense terminal.

According to the present disclosure, optimization of switching characteristics and a higher power density of a semiconductor device can be achieved.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a semiconductor device according to Embodiment 1;

FIG. 2 is a cross-sectional view of the semiconductor device according to Embodiment 1;

FIG. 3 is a cross-sectional view of a semiconductor device according to Embodiment 2;

FIG. 4 is a cross-sectional view of a semiconductor device according to Embodiment 3; and

FIG. 5 is a cross-sectional view of a semiconductor device according to Embodiment 4.

### DESCRIPTION OF THE PREFERRED EMBODIMENTS

### Embodiment 1

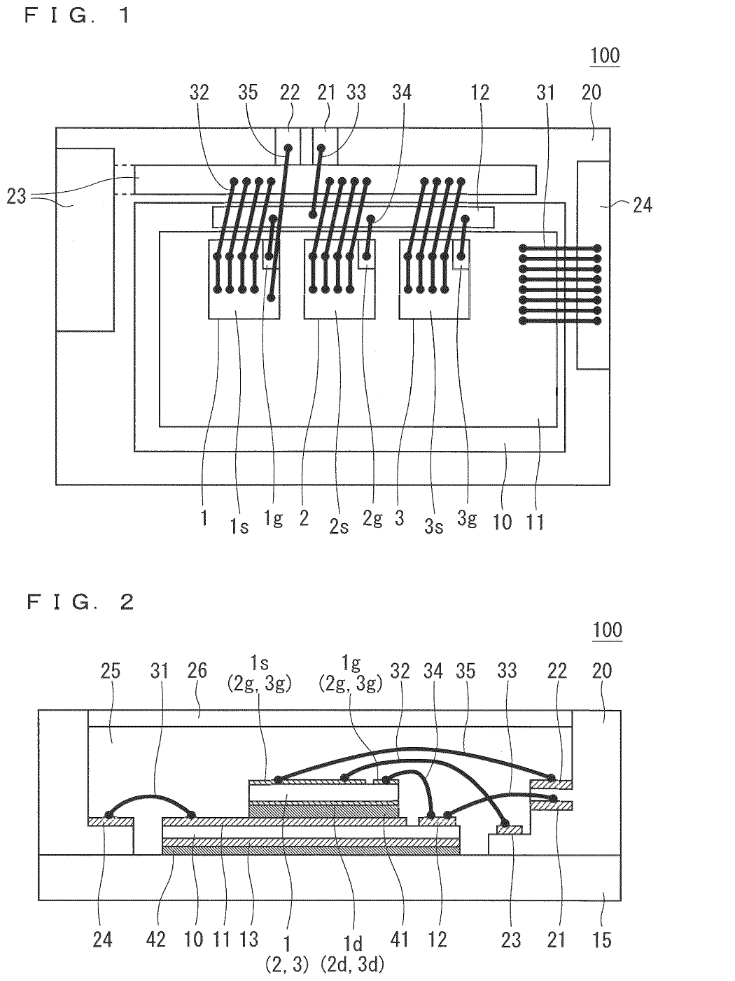

FIG. 1 and FIG. 2 are diagrams illustrating a configuration of a semiconductor device 100 according to Embodiment 1 and are respectively a plan view and a cross-sectional view of the semiconductor device 100.

The semiconductor device 100 includes a plurality of semiconductor chips mounted to an insulating substrate 10. The insulating substrate 10 is formed of ceramics, for example. In the present embodiment, an example in which a first semiconductor chip 1, a second semiconductor chip 2, and a third semiconductor chip 3 are mounted to the insulating substrate 10 as the plurality of semiconductor chips is shown. The first semiconductor chip 1, the second semiconductor chip 2, and the third semiconductor chip 3 are power control switching elements, such as metal oxide semiconductor field effect transistors (MOSFETs) and insulated gate bipolar transistors (IGBTs). The first semiconductor chip 1 is representatively illustrated in FIG. 2.

The first semiconductor chip 1 has a source electrode 1s and a gate electrode 1g on an upper surface and a drain electrode 1d on a lower surface. The second semiconductor chip 2 has a source electrode 2s and a gate electrode 2g on an upper surface and a drain electrode 2d on a lower surface. The third semiconductor chip 3 has a source electrode 3s and a gate electrode 3g on an upper surface and a drain electrode 3d on a lower surface.

A drain pattern 11 and a gate pattern 12 each formed, for example, of copper are formed over an upper surface of the insulating substrate 10, and the drain electrode 1d of the first semiconductor chip 1, the drain electrode 2d of the second semiconductor chip 2, and the drain electrode 3d of the third semiconductor chip 3 are each bonded to the drain pattern 11 with a bonding material 41, such as solder.

A metal pattern 13 formed, for example, of copper is formed over a lower surface of the insulating substrate 10 and is bonded to a base plate 15 of copper with a bonding material 42, such as solder.

A case 20 housing the insulating substrate 10 and the first semiconductor chip 1, the second semiconductor chip 2, and the third semiconductor chip 3 mounted to the insulating substrate 10 is bonded to a peripheral edge of the base plate 15. The case 20 has a gate terminal 21 and a source sense terminal 22 as signal terminals and a source terminal 23 and a drain terminal 24 as main terminals through which a high current flows. These terminals have been insert molded in the case 20. Use of not outsert molded electrodes but insert molded electrodes can contribute to reduction in assembly flow.

The gate terminal 21, the source sense terminal 22, and the source terminal 23 are arranged along the same side of the case 20. The gate terminal 21 and the source sense terminal 22 are arranged outside the source terminal 23. The gate terminal 21 and the source sense terminal 22 are at different heights. The source terminal 23 is at a smaller height than the gate terminal 21 and the source sense terminal 22. The gate pattern 12 over the insulating substrate 10 is disposed between the drain pattern 11 and the source terminal 23.

The drain terminal 24 is connected to the drain pattern 11 via first wires 31. The source terminal 23 is connected to the source electrode 1s of the first semiconductor chip 1, the source electrode 2s of the second semiconductor chip 2, and the source electrode 3s of the third semiconductor chip 3 via second wires 32.

The gate terminal 21 is connected to the gate pattern 12 via a third wire 33. The gate pattern 12 is connected to the gate electrode 1g of the first semiconductor chip 1, the gate electrode 2g of the second semiconductor chip 2, and the gate electrode 3g of the third semiconductor chip 3 via fourth wires 34.

The source sense terminal 22 is connected to any one of the source electrode 1s of the first semiconductor chip 1, the source electrode 2s of the second semiconductor chip 2, and the source electrode 3s of the third semiconductor chip 3 via a fifth wire 35.

The case 20 is filled with a sealing material 25, and an opening of the case 20 is covered with a lid 26.

According to the semiconductor device 100 according to Embodiment 1, the gate terminal 21 and the source sense terminal 22 as the signal terminals are at different heights to increase freedom of wire bonding, so that a complex circuit configuration can be achieved while the commonality of members is maintained, and switching characteristics can be optimized. The source terminal 23 is disposed on a lowermost step, so that the second wires 32, which are main wires through which a high current flows, can be reduced in lengths to suppress heat generation to contribute to a higher power density of the semiconductor device 100.

In Embodiment 1, the source sense terminal 22 is at a greater height than the gate terminal 21. That is to say, the descending order of heights is: the source sense terminal 22, the gate terminal 21, and the source terminal 23. Positive feedback and negative feedback during switching operation can thereby appropriately be controlled by separately applying a reference potential for a source sense.

Furthermore, in Embodiment 1, as illustrated in FIG. 1, the third wire 33 connected to the gate terminal 21 and the fifth wire 35 connected to the source sense terminal 22 are parallel in plan view. The first semiconductor chip 1, the second semiconductor chip 2, and the third semiconductor chip 3 as switching elements are susceptible to a source impedance, and a current balance among the chips is likely to be lost, but, when the fifth wire 35 connected to the source sense terminal 22 does not intersect with the third wire 33 connected to the gate terminal 21, the reference potential for the source sense can be optimized, and improvement in current balance can be expected.

When the first semiconductor chip 1, the second semiconductor chip 2, and the third semiconductor chip 3 are formed of a wide bandgap semiconductor, such as silicon carbide (SiC), they are assumed to be driven at a high speed. When the first semiconductor chip 1, the second semiconductor chip 2, and the third semiconductor chip 3 are driven at a high speed, switching is greatly affected by a variation in source impedance, so that parallel arrangement of the third wire 33 and the fifth wire 35 is particularly effective when the first semiconductor chip 1, the second semiconductor chip 2, and the third semiconductor chip 3 are formed of a wide bandgap semiconductor.

### Embodiment 2

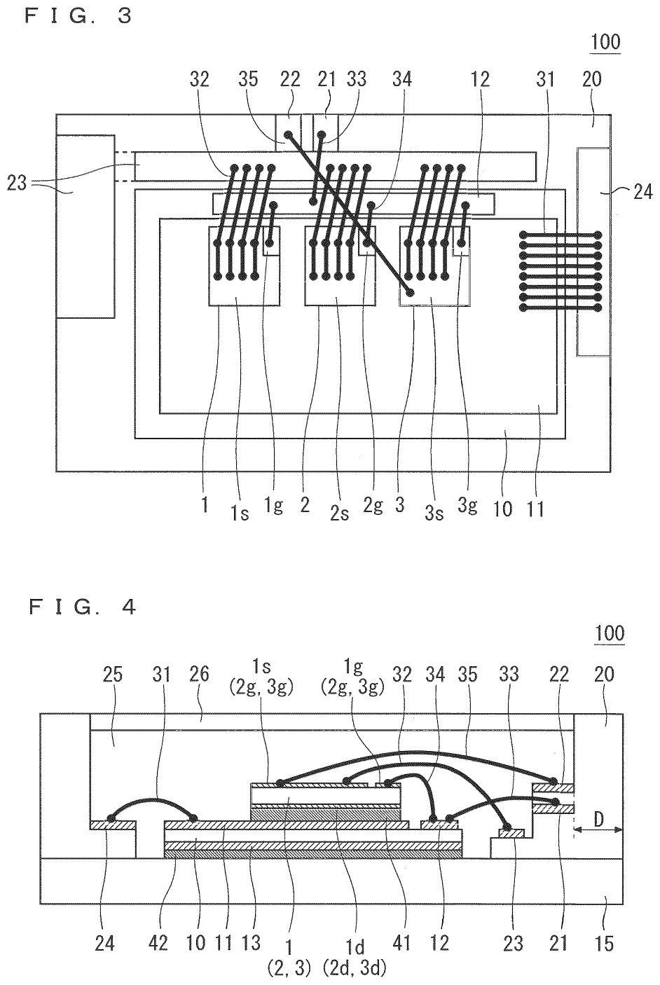

FIG. 3 is a plan view illustrating a configuration of a semiconductor device 100 according to Embodiment 2. A cross-sectional view of the semiconductor device 100 is similar to that in FIG. 2.

In the semiconductor device 100 according to Embodiment 2, the fifth wire 35 connected to the source sense terminal 22 intersects with both of the second wires 32 connected to the source terminal 23 and the third wire 33 connected to the gate terminal 21 in plan view. A complex circuit configuration can thereby be achieved with less space.

However, it should be noted that, when the third wire 33 and the fifth wire 35 intersect with each other, the first semiconductor chip 1, the second semiconductor chip 2, and the third semiconductor chip 3 as the switching elements are susceptible to the source impedance as described above.

### Embodiment 3

FIG. 4 is a cross-sectional view illustrating a configuration of a semiconductor device 100 according to Embodiment 3. A plan view of the semiconductor device 100 is similar to that in FIG. 1 or FIG. 3.

In the semiconductor device 100 according to Embodiment 3, a distance D from a side surface of the case 20 to the source sense terminal 22 and the gate terminal 21 is 3.0 mm or more. Reliability of the semiconductor device 100 and strength of the semiconductor device 100 during assembly are thereby improved.

### Embodiment 4

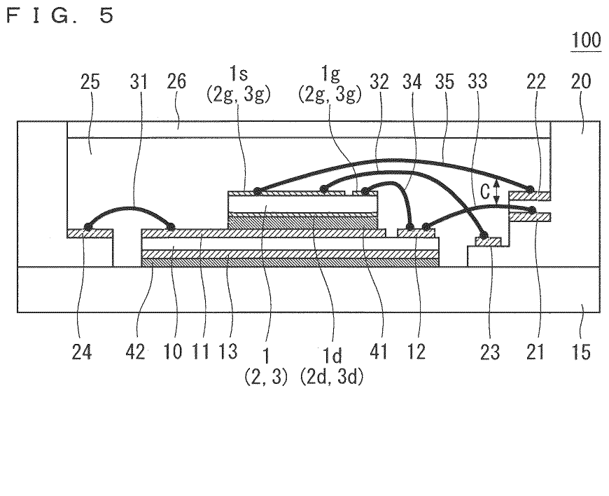

FIG. 5 is a cross-sectional view illustrating a configuration of a semiconductor device 100 according to Embodiment 4. A plan view of the semiconductor device 100 is similar to that in FIG. 1 or FIG. 3.

In the semiconductor device 100 according to Embodiment 4, spacing C between the third wire 33 connected to the gate terminal 21 and the fifth wire 35 connected to the source sense terminal 22 is 3.0 mm or more.

For example, a customer who has purchased a product of the semiconductor device 100 might mistake the source sense terminal 22 for a drain sense terminal when the semiconductor device 100 is installed and wired, but, by securing the spacing C between the third wire 33 and the fifth wire 35 of 3.0 mm or more, discharge between a drain and a gate or discharge between the drain and a source can be prevented to prevent discharge breakdown. Assuming that air has an insulating tolerance per 1 mm of 1 kV, the semiconductor device 100 is designed not to cause discharge breakdown even when a voltage of 3 kV or more is applied across the drain and the gate or across the drain and the source.

Embodiments can freely be combined with each other and can be modified or omitted as appropriate.

### APPENDICES

Various aspects of the present disclosure will collectively be described below as appendices.

### (Appendix 1)

A semiconductor device comprising:
an insulating substrate;
a drain pattern and a gate pattern formed over an upper surface of the insulating substrate;
a plurality of semiconductor chips each having a drain electrode on a lower surface and a source electrode and a gate electrode on an upper surface, the drain electrode being bonded to the drain pattern; and
a case housing the plurality of semiconductor chips and having a gate terminal, a source sense terminal, a source terminal, and a drain terminal, wherein
the drain terminal is connected to the drain pattern via a first wire,
the source terminal is connected to the source electrode of each of the plurality of semiconductor chips via a second wire,
the gate terminal is connected to the gate pattern via a third wire,
the gate pattern is connected to the gate electrode of each of the plurality of semiconductor chips via a fourth wire,
the source sense terminal is connected to the source electrode of any one of the plurality of semiconductor chips via a fifth wire,
the gate terminal and the source sense terminal are at different heights, and
the source terminal is at a smaller height than the gate terminal and the source sense terminal.

### (Appendix 2)

The semiconductor device according to Appendix 1, wherein
the source sense terminal is at a greater height than the gate terminal.

### (Appendix 3)

The semiconductor device according to Appendix 1 or 2, wherein
the third wire and the fifth wire are parallel in plan view.

### (Appendix 4)

The semiconductor device according to Appendix 3, wherein
the plurality of semiconductor chips are formed of a wide bandgap semiconductor.

### (Appendix 5)

The semiconductor device according to Appendix 1 or 2, wherein
the fifth wire intersects with both of the second wire and the third wire in plan view.

### (Appendix 6)

The semiconductor device according to any one of Appendices 1 to 5, wherein
a distance from a side surface of the case to the source sense terminal and the gate terminal is 3.0 mm or more.

### (Appendix 7)

The semiconductor device according to any one of Appendices 1 to 6, wherein
spacing between the third wire and the fifth wire is 3.0 mm or more.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
an insulating substrate;
a drain pattern and a gate pattern formed over an upper surface of the insulating substrate;
a plurality of semiconductor chips each having a drain electrode on a lower surface and a source electrode and a gate electrode on an upper surface, the drain electrode being bonded to the drain pattern; and
a case housing the plurality of semiconductor chips and having a gate terminal, a source sense terminal, a source terminal, and a drain terminal, wherein
the drain terminal is connected to the drain pattern via a first wire,
the source terminal is connected to the source electrode of each of the plurality of semiconductor chips via a second wire,
the gate terminal is connected to the gate pattern via a third wire,
the gate pattern is connected to the gate electrode of each of the plurality of semiconductor chips via a fourth wire,
the source sense terminal is connected to the source electrode of any one of the plurality of semiconductor chips via a fifth wire,
the gate terminal and the source sense terminal are at different heights, and
the source terminal is at a smaller height than the gate terminal and the source sense terminal.

2. The semiconductor device according to claim 1, wherein
the source sense terminal is at a greater height than the gate terminal.

3. The semiconductor device according to claim 1, wherein
the third wire and the fifth wire are parallel in plan view.

4. The semiconductor device according to claim 3, wherein
the plurality of semiconductor chips are formed of a wide bandgap semiconductor.

5. The semiconductor device according to claim 1, wherein
the fifth wire intersects with both of the second wire and the third wire in plan view.

6. The semiconductor device according to claim 1, wherein
a distance from a side surface of the case to the source sense terminal and the gate terminal is 3.0 mm or more.

7. The semiconductor device according to claim 1, wherein
spacing between the third wire and the fifth wire is 3.0 mm or more.
